(19) United States
(12) Patent Application Publication
(10) Pub. No.: US 2006/0157692 A1
(43) Pub. Date: Jul. 20, 2006

(54) Organic transistor and manufacturing method thereof

(75) Inventors: Takatsugu Wada, Sagamihara-shi (JP); Hiroyuki Tokunaga, Fujisawa-shi (JP); Osamu Kanome, Yokohama-shi (JP); Mika Hanada, Tokyo (JP); Takehito Nishida, Tokyo (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/370,924

(22) Filed: Mar. 9, 2006

Related U.S. Application Data
(63) Continuation of application No. PCT/JP05/20399, filed on Nov. 1, 2005.

(30) Foreign Application Priority Data
Nov. 2, 2004 (JP) 2004-319737

(51) Int. Cl. H01L 29/08; H01L 21/84

(52) U.S. Cl. 257/40; 257/E51.006; 257/347; 438/149

(57) ABSTRACT

There is provided an organic transistor having a bottom gate structure, composed of a substrate, a gate electrode, a gate insulating layer, source and drain electrodes and an organic semiconductor layer, wherein the gate insulating layer is formed so as to have a low surface energy in a portion thereof in proximity to the source and drain electrodes and a relatively high surface energy in a portion in proximity to the gate electrode, and consist of different compositions in a layer thickness direction, whereby an organic transistor has a short channel and high electric characteristics; as well as a method of manufacturing the organic semiconductor.

This application is a continuation of International Application No. PCT/JP2005/020399 filed on Nov. 1, 2005, which claims the benefit of Japanese Patent Application No. 2004-319737 filed on Nov. 2, 2004.

### BACKGROUND OF THE INVENTION

1. Field of the Invention

The present invention relates to an organic transistor having an organic semiconductor material and a manufacturing method thereof, and specifically to an organic transistor formed by ink-jet drawing process and a manufacturing method thereof.

2. Related Background Art

In recent years, research on organic electronic devices using organic materials has been flourishing. Realization of costly inexpensive organic electronic devices that are excellent in lowering process temperature and portability is expected by applying thin film formation of organic materials to devices.

For example, research on organic electronic devices such as organic ELs and organic transistors etc. is flourishing. Among them, since a semiconductor material itself which is the most vital part of functions of the organic transistor is an aggregate of organic molecules, and partially covalently-bonded and comparatively weak bonded body, the organic transistor is promising in lowering process temperature and abundant in flexibility to enable reduction in weight, whereby it is excellent in portability. Hence, there is a possibility of application to liquid crystal displays as well as paper-like displays, rapidly making such research active in recent years. As a method for realizing application of organic electronic devices to such a field of electronic devices, a method of making organic transistors utilizing an ink-jet drawing process is nominated, and applications to next-generation low-temperature process and highly portable electronic devices are expected.

With respect to making organic transistors, a variety of methods are nominated, and for example, a method of making organic transistors in use of surface mapping by way of a piezoelectric ink-jet drawing process and surface free energy control by Seiko Epson Corporation is described in “Science” 280, 2123 in 2000 and “Tech Digest of IEDM”, p. 623 in 2000 and the like.

On the other hand, “Extended Abstracts of the 2003 International Conference on Solid State Devices and Materials” p. 222 to 223 in 2003 discloses a process of making organic transistors with short channels, including the steps of using a self-assembled monolayer (SAM), increasing the surface free energy of a portion irradiated with UV light by exposure of UV light from substrate back surface, mapping the surface of the self-assembled monolayer (SAM) by giving contrast against the low surface free energy of non-exposed portions, causing Ag ink to drop to portions having a high surface free energy to draw source and drain electrodes, and making an organic transistor with short channels.

In addition, “Digest of technical papers AM-LCD 04 OLED-4” p. 37 to 40 discloses a process of manufacturing transistors with short channels by increasing the surface free energy of a portion irradiated with light by mask exposure of UV light using polyimide as an insulating film, mapping a polyimide surface by giving contrast against the low surface free energy of non-exposed portions and drawing source and drain electrodes to portions having high surface free energy.

According to the above-described report on “Extended Abstracts of the 2003 International Conference on Solid State Devices and Materials” p. 222 to 223 in 2003, the method of mapping a self-assembled monolayer (SAM) with UV light makes it impossible to vary the surface free energy of the self-assembled monolayer (SAM) by using UV light other than the vacuum ultraviolet light of 200 nm or less. Accordingly, in order to implement highly fine patterning of a surface free energy, significantly expensive stepper using a vacuum UV light of 200 nm or less has to be used, which is unrealistic as a process of manufacturing an organic transistors.

In addition, as reported by “Extended Abstracts of the 2003 International Conference on Solid State Devices and Materials” p. 222 to 223 in 2003, any back-surface exposure makes it possible to carry out patterning of surface free energy of a self-assembled monolayer (SAM), but because of utilizing a gate electrode in order to implement patterning, a gate electrode has to be formed with photolithography. In addition, due to implementation of back surface exposure, a substrate material is expected to be limited due to the light-absorbing property of the substrate. Moreover, highly fine patterning is slightly difficult due to implementation of exposure using the gate electrode as a mask in the back surface exposure.

On the other hand, in the method of mapping a polyimide insulating film with UV light according to “Digest of technical papers AM-LCD 04 OLED-4” p. 37 to 40, the material existing on the channel interface and the insulating film are integral. In this case, in case of applying an orientated organic semiconductor to a channel portion, orientation cannot be controlled and sufficient electric performance that the semiconductor material has cannot be drawn out. In addition, it is possible to design polyimide so that patterning of a surface free energy is implemented with UV light of 254 nm, which however occasionally gives rise to decrease in insulating performance.

### SUMMARY OF THE INVENTION

In a mode of the present invention, an object of the present invention is to realize an organic transistor having a short channel and high electric characteristics, which is formed by patterning of surface free energy with general UV light of 254 nm as UV light wavelength of an exposure system and, consequently, implements highly fine patterning of surface free energy with an inexpensive aligner. Moreover, another object of the present invention is to realize an organic transistor having a short channel and high electric characteristics and including a layer having a function of controlling orientation and a material excellent in insulating performance which are separated.

In addition, in another mode of the present invention, an object of the present invention is to accurately form a gate electrode by providing a substrate insulating layer on a substrate, subjecting the substrate insulating layer to highly fine patterning of surface free energy with UV light of 254 nm without using vacuum process or photolithography.

At least one among the above-described objects is achieved by any one of the following inventions.

Firstly, the present invention provides an organic transistor having a bottom gate structure, including a substrate, a gate electrode, a gate insulating layer, source and drain electrodes, and an organic semiconductor layer, wherein the gate insulating layer has a low surface energy in a portion thereof in proximity to the source and drain electrodes and a relatively high surface energy in a portion thereof in proximity to the gate electrode, and has different compositions in a layer thickness direction.

In such an organic transistor, the above-described gate insulating layer having different compositions in a layer thickness direction preferably has a double layer structure composed of an upper layer having a relatively low surface energy and a lower layer having a relatively high surface energy.

In addition, the above-described gate insulating layer, the upper layer preferably has a surface free energy of 40 mN/m or less and the lower layer has a surface free energy of 45 mN/m or more.

A portion of the upper insulating layer of the gate insulating layer upper layer in contact with a part or all of the source and drain electrodes preferably has a surface free energy of 50 mN/m or more.

In addition, the present invention provides the above-described organic transistor, wherein in a portion of the above-described gate insulating layer having a double layer structure composed of the upper layer and the lower layer, a hydrogen bonding component of surface free energy of the above-described upper insulating layer is 1.0 mN/m or less, and a hydrogen bonding component of surface free energy of the above-described lower insulating layer 2.0 mN/m or more, and a hydrogen bonding component of surface free energy of a portion of an insulating layer connected continuously with the above-described upper insulating layer and adjacent to a part or all of the source and drain electrodes is 5.0 mN/m or more.

In addition, the present invention provides the above-described organic transistor, wherein in a portion of the gate insulating layer having a double layer structure composed of the above-described upper layer and lower layer, the above-described upper insulating layer is polyimide containing an alkyl group in a side chain thereof, and the above-described lower insulating layer is polyimide having no alkyl group.

In addition, the present invention provides the above-described organic transistor, wherein in a portion of the gate insulating layer having a double layer structure composed of the above-described upper layer and lower layer, the above-described upper insulating layer is polyimide containing an alkyl group in a side chain thereof, and the above-described lower insulating layer is made of an inorganic insulating material.

In addition, the present invention provides the above-described organic transistor, wherein a portion of the gate insulating layer having a double layer structure composed of the above-described upper layer and lower layer, the film thickness of the above-described upper insulating layer is thinner than the thickness of the above-described lower insulating layer.

In addition, the present invention provides the above-described organic transistor, wherein a portion of the gate insulating layer having a double layer structure composed of the above-described upper layer and lower layer, the film thickness of the above-described upper insulating layer is 2 nm or more and 200 nm or less, and the above-described lower insulating layer is 100 nm or more.

In addition, the present invention provides a method of manufacturing an organic transistor including a substrate, a gate electrode, a stacked gate insulating composed of two or more layers, source and drain electrodes, and an organic semiconductor layer, which method includes the steps of:

subjecting the above-described stacked gate insulating layer composed of two or more layers to mask exposure with ultraviolet rays having a wavelength band of 200 nm or more and 300 nm or less,

discharging an electrode material for forming source and drain onto a portion subjected to the above-described mask exposure by an ink-jet method, and

separating the electrode material difference in surface free energy between the portion subjected to the mask exposure and the other portion not subjected to the mask exposure to form a channel.

In addition, the present invention provides the above-described method of manufacturing an organic transistor, wherein prior to the step of subjecting the above-described stacked gate insulating layer composed of two layers to mask exposure with ultraviolet rays having a wavelength band of 200 nm or more and 300 nm or less, the above-described stacked gate insulating layer composed of two or more layers is subjected to a rubbing treatment.

In addition, the present invention provides the above-described method of manufacturing an organic transistor, wherein prior to or after the step subjecting the above-described stacked gate insulating layer composed of two or layers to the mask exposure with ultraviolet rays having a wavelength band of 200 nm or more and 300 nm or less, the above-described stacked gate insulating layer composed of two or more layers is subjected to irradiation of polarized ultraviolet light.

In addition, the present invention provides an organic transistor having a bottom gate structure with a plurality of insulating layers, including a substrate, a gate electrode, a substrate insulating layer located between the substrate and the gate electrode, a gate insulating layer, source and drain electrodes, and an organic semiconductor layer, wherein the gate insulating layer has a low surface energy being in a portion in proximity to the source and drain electrodes and a high surface energy in a portion in proximity to the gate electrode, and has different compositions in a layer thickness direction, and a surface free energy of the substrate insulating layer is lower than a surface free energy in a portion in proximity to the gate electrode.

In addition, the present invention provides the above-described organic transistor having a bottom gate structure, including a substrate, a gate electrode, a substrate insulating layer located between the substrate and the gate electrode, a gate insulating layer, source and drain electrodes, and an organic semiconductor layer, wherein the gate insulating layer consists of an upper layer having a low surface energy and a lower layer having a high surface energy, and a surface free energy of the substrate insulating layer is lower than the high surface free energy of the lower layer of the above-described gate insulating layer.

In addition, the present invention provides the above-described organic transistor, wherein the upper layer of the above-described gate insulating layer has a surface free energy of 40 mN/m or less, the lower layer of the gate insulating layer has a surface free energy of 45 mN/m or more, and the above-described substrate insulating layer has a surface free energy of 45 mN/m or more.

In addition, the present invention provides the above-described organic transistor, wherein the upper layer of the above-described gate insulating layer is an insulating layer having a surface free energy of 50 mN/m or more adjacent to a part or all of the source and drain electrodes, and the above-described substrate insulating layer is an insulating layer having a surface free energy of 50 mN/m or more adjacent to a part or all of the gate electrode.

In addition, the present invention provides the above-described organic transistor, wherein in the above-described gate insulating layer, a hydrogen bonding component of surface free energy of the above-described upper insulating layer is 1.0 mN/m or less and a hydrogen bonding component of surface free energy of the above-described lower insulating layer is 2.0 mN/m or more, and a hydrogen bonding component of surface free energy of a portion of an insulating layer connected continuously with the above-described upper insulating layer and adjacent to a part or all of the above-described source and drain electrodes is 5.0 mN/m or more; and wherein in the above-described substrate insulating layer, a hydrogen bonding component of surface free energy is 1.0 mN/m or less, and a hydrogen bonding component of surface free energy of a portion of an insulating layer connected continuously with the above-described substrate insulating layer and adjacent to a part or all of the above-described gate electrode is 5.0 mN/m or more.

Here, the surface free energy is stipulated by three components, i.e., dispersion component, polarity component and hydrogen bonding component from the extended Fowkes equation.

In addition, the present invention provides the above-described organic transistor wherein in the above-described substrate insulating layer and the above-described gate insulating layer, the substrate insulating layer and the upper layer of the gate insulating layer are polyimide containing an alkyl group in a side chain, and the lower layer of the gate insulating layer is polyimide containing no alkyl group in a side chain.

In addition, the present invention provides the above-described organic transistor wherein in the above-described substrate insulating layer and the above-described gate insulating layer, the substrate insulating layer and the upper layer of the gate insulating layer are polyimide containing an alkyl group in a side chain, and the lower layer of the gate insulating layer is made of an inorganic insulating material.

In addition, the present invention provides the above-descried organic transistor wherein in the above-described substrate insulating layer and the above-described gate insulating layer, the layer thickness of the substrate insulating layer and the layer thickness of the upper layer of the gate insulating layer are thinner than layer thickness of the lower layer of the gate insulating layer.

In addition, the present invention provides the above-described organic transistor wherein in the above-described substrate insulating layer and the above-described gate insulating layer, the layer thickness of the substrate insulating layer and the layer thickness of the upper layer of the gate insulating layer are 2 nm or more and 200 nm or less, and the layer thickness of the lower layer of the gate insulating layer is 100 nm or more.

In addition, the present invention provides a method of manufacturing an organic transistor including a plurality of insulating layers and including a substrate, a gate electrode, a substrate insulating layer located between the substrate and the gate electrode, a stacked gate insulating layer composed of two or more layers, source and drain electrodes, and an organic semiconductor layer, which method comprises the steps of:

subjecting the above-described substrate insulating layer and the above-described gate insulating layer to mask exposure with ultraviolet rays (UV light) having a wavelength band of 200 nm or more and 300 nm or less;

discharging an electrode material for forming a gate electrode onto a part or all of a portion subjected to the mask exposure of the substrate insulating layer by an ink-jet method such that the electrode material expands to the portion subjected to the mask exposure to form a gate electrode; and

discharging an electrode material for forming source and drain electrodes to the portion subjected to the mask exposure of the gate insulating layer by an ink-jet method, separating the electrode material by a difference in surface free energy between the portion subjected to the mask exposure and the other portion not subjected to the mask exposure to form a channel.

In addition, the present invention provides the above-described method of manufacturing an organic transistor, wherein prior to the step of subjecting the above-described stacked gate insulating layer composed of two or more layers to the mask exposure with ultraviolet rays having a wavelength band of 200 nm or more and 300 nm or less, the stacked gate insulating layer composed of two or more layers is subjected to a rubbing treatment.

In addition, the present invention provides the above-described method of manufacturing an organic transistor, wherein prior to or after subjecting the above-described stacked gate insulating layer composed of two or more layers to the mask exposure with ultraviolet rays having a wavelength band of 200 nm or more and 300 nm or less, the stacked gate insulating layer composed of two or more layers is subjected to irradiation of polarized ultraviolet light.

Here, the above-described inventions can be appropriately combined to a not contradictory extent.

In addition, it goes without saying that, among those of the above-described inventions based on the premise of the stacked gate insulating layer, for those irrelevant to thickness, “upper layer” and “lower layer” read respectively as “portion of a gate insulating layer in proximity to source and drain electrodes of the gate insulating layer” and “portion of a gate insulating layer in proximity to a gate electrode of the gate insulating layer” to enable to regard as an invention relating to an organic transistor including no stacked gate insulating layer.

### BRIEF DESCRIPTION OF THE DRAWINGS

FIG. 1 is a sectional diagram of an organic transistor of a bottom gate type in case of including double insulating layer structure consisting of an insulating layer made of polyimide containing an alkyl group in a side chain and an insulating layer made of polyimide containing no alkyl group, as an example of the present invention;

FIG. 2 is a conceptual diagram of orientation control by rubbing applicable to the present invention;

FIG. 3 is a conceptual diagram of orientation control by polarized UV light applicable to the present invention;

FIG. 4 is a graph showing variations in contact angle of water of polyimide containing an alkyl group in a side chain against 254 nm UV light irradiation amount, which is applied for description of experiments of the present invention;

FIG. 5 is a graph showing changes in total surface free energy of polyimide containing an alkyl group in a side chain against 254 nm UV light irradiation amount, which is applied for description of experiments of the present invention;

FIG. 6 is a graph showing variations in each component of surface free energy of polyimide containing an alkyl group in a side chain against 254 nm UV light irradiation amount, which is applied for description of experiments of the present invention;

FIG. 7 is a graph showing a relationship between a stock solution concentration of polyimide containing an alkyl group in a side chain and a film (layer) thickness, which is applied for description of experiments of the present invention;

FIG. 8 is a graph showing dependency of change in contact angle of water of polyimide containing an alkyl group in a side chain on film (layer) thickness against 254 nm UV light irradiation, which is applied for description of experiments of the present invention;

FIG. 9 is an optical microscope photograph showing a particle structure after ink-jet drawing of Au nano ink onto polyimide with surface free energy subjecting to mapping so as to set channel length=5 μm with 254 nm UV light irradiation, which is applied for description of embodiments of the present invention;

FIG. 10 is a graph showing a result of experiments having checked influence to Vth by forming the insulating film of a transistor with a stacked structure of polyimide containing an alkyl group in a side chain and polyimide containing no alkyl group and causing respective film thickness to vary;

FIGS. 11A and 11B are diagrams showing steps of implementing surface energy control of orientated film with UV light according to the present invention;

FIG. 12 is a sectional diagram of an organic transistor of a bottom gate type in case of including a double insulating layer structure consisting of an insulating layer made of polyimide containing an alkyl group in a side chain and an insulating layer made of polyimide containing no alkyl group and a substrate insulating layer, as an example of the present invention;

FIG. 13 is a conceptual diagram of orientation control by rubbing applicable to the present invention;

FIG. 14 is a conceptual diagram of orientation control by polarized UV light applicable to the present invention;

FIGS. 15A and 15B are diagrams showing steps of implementing surface energy control of a substrate insulating layer with UV light according to the present invention; and

FIGS. 16A, 16B, 16C and 16D are diagrams showing steps of forming a gate electrode with an ink-jet subject to surface energy control of a substrate insulating layer with UV light according to the present invention.

### DESCRIPTION OF THE PREFERRED EMBODIMENTS

According to a preferable embodiment of the present invention, in the configuration of an organic transistor, by forming a double insulating layer structure consisting of an insulating layer made of polyimide containing an alkyl group in a side chain and an insulating layer made of polyimide containing no alkyl group and subjecting a channel portion on its insulating layer to masking to undergo irradiation with Deep UV light, surface free energy can be controlled to become low in channel portion and high in non-channel portion, and precise control of a channel becomes feasible with an ink-jet method using its surface free energy distribution.

In addition, by the insulating layer made of polyimide containing no alkyl group, decrease in breakdown voltage of an insulating layer made of polyimide containing an alkyl group in a side chain and increase in Vth are covered so that highly reliable transistor with a high breakdown voltage and a low leak current and high performance can be realized.

In addition, a rubbing treatment or irradiation of polarized UV light is carried out for an insulating film made of polyimide containing an alkyl group in a side chain to arrange organic semiconductor layers formed onto an orientated film in channel portions in one direction, an orientated structure that can realize extremely high mobility can be realized.

According to a preferable embodiment of the present invention, in a structure of an organic transistor, by forming, as the substrate insulating film, an organic insulating layer made of polyimide containing an alkyl group in a side chain, subjecting a portion other than a gate on this substrate insulating layer to masking, and subjecting only the gate portion to irradiation with Deep UV light, whereby surface free energy of the gate portion can be controlled high and surface free energy of the portion other than the gate can be controlled low, and precise control of the gate becomes feasible with an ink-jet method using its surface free energy distribution.

In addition, by forming, as a gate insulating layer, a double insulating layer structure of an organic insulating layer made of polyimide containing an alkyl group in a side chain and an insulating layer made of polyimide not containing it, masking a channel portion on this gate insulating layer, and carrying out irradiation with Deep UV light, surface free energy of the channel portion can be controlled low and surface free energy of the portion other than the channel portion can be controlled high, and precise control of the channel becomes feasible with an ink-jet method using its surface free energy distribution.

In addition, by an insulating layer made of polyimide containing no alkyl group, decrease in breakdown voltage of an insulating layer made of polyimide containing an alkyl group in a side chain and increase in Vth are covered so that highly reliable transistor with a high breakdown voltage and a low leak current and high performance can be realized. In addition, the implementing rubbing treatment or the irradiation of polarized UV light onto an insulating film made of polyimide containing an alkyl group in a side chain makes it possible to arrange organic semiconductor layers formed in one direction on an alignment film in channel portions, whereby an orientated structure that can realize extremely high mobility can be realized.

In addition, utilizing this structure, excellent organic transistor can be realized. In addition, an organic transistor of the present invention can be expected to be applied to a variety of electronic devices such as a paper-like display, an organic ID tag, an organic EL.

As a technique of forming channels and improving mobility of an organic transistor, the present inventors focused attention on an organic substance having a low surface free energy that was decomposable with ultraviolet rays. This is to derive surface free energy becoming low prior to decomposition with ultraviolet rays and derive surface free energy becoming high after the decomposition. Keeping a low surface free energy by protecting an organic substance on a gate with a mask and deriving a high surface free energy by decomposing an organic substance in the vicinity thereof with ultraviolet rays makes it possible to dam ink in portions with low surface free energy at the time of drawing source and drain electrodes with an electrically conductive ink with drawing method such as ink-jet, whereby extremely accurate gate-likewise, as for organic substance in portions corresponding to a gate on a substrate, the organic substance is decomposed with ultraviolet rays to make its surface free energy high, a portions in the vicinity thereof are protected with a mask to keep its surface free energy low, and therefore ink spreads over portions with high surface free energy at the time of drawing a gate electrode and is dammed in portions with low surface free energy, whereby an extremely accurate gate-electrode can be formed.

As wavelength of ultraviolet rays used in the present invention, any wavelength that can decompose organic substance may be used, but ultraviolet rays having wavelength around 254 nm are preferably used, considering that fine patterns can be made and from a point of view of costs of apparatus.

Among these organic substances, an alignment film comprising a polymeric compound gives rise to alignment regulation force by rubbing treatment or polarized ultraviolet rays irradiation, and the force can orient organic semiconductor molecules on a gate (channel portion interface), whereby this enables planning of improvement in organic transistor properties such as improvement in mobility and therefore is preferable. An example of the alignment film comprising a polymeric compound used in the present invention includes polyimide containing an alkyl group in a side chain.

On the other hand, an alignment film comprising a polymeric compound such as polyimide containing an alkyl group in a side chain is the one having been developed by focusing attention on orientation control, and there are quite a few cases that performance as a gate insulating layer is insufficient.

Therefore, it has been found to be possible to satisfy improvement in transistor properties in terms of the above-described insulation, highly precise gate length stipulation and orientation control by forming, on the gate, insulating film of a polymeric system such as polyimide and polyolefin containing no alkyl group in a side chain and insulating film of inorganic oxide system such as SiO₂ and Ta₂O₅, that are excellent in insulation, and stacking thereon polymeric orientation film such as polyimide containing an alkyl group in a side chain as a low surface free energy organic substance that is decomposable with ultraviolet rays. Moreover, it has been found to be possible to satisfy improvement in transistor properties in terms of the above-described highly precise gate electrode formation, insulating property, highly precise channel length stipulation and orientation control, by stacking also on substrate an alignment film comprising a polymeric compound such as polyimide containing an alkyl group in a side chain as a low surface free energy organic substance that is decomposable with ultraviolet rays.

Among them, a polymeric insulating film having a skeleton like an alignment film comprising a polymeric compound provides good tight contact with the alignment film comprising a polymeric compound, and therefore can be used preferably in case of forming an organic transistor onto a flexible substrate.

The present inventors hereof have implemented experimental study as follows for reaching the present invention, and details thereof will be described.

(Experiment 1)

Relationship of density of alkyl group, surface free energy (surface E), surface free energy hydrogen bonding term, water repellency and leak current will be described in the following Table 1. Table 1 shows relationship of density of alkyl group, surface free energy, hydrogen bonding term, water repellency and leak current in respective kinds of insulating films which are applied for describing experiments of the present invention.

TABLE 1

| | | | Hydrogen | | |
|---|---|---|---|---|---|
| Insulating | Alkyl | Surface E | bonding | Water | |
| film | group | (mN/m) | (mN/m) | repellency | Leak |
| A | None | 50 | 3.1 | x | |
| B | None | 49 | 2.5 | x | ∘ |
| C | None | 45 | 2.0 | x | Δ |
| D | Small | 40 | 1.0 | ∘ | x |
| | density | | | | |
| E | Middle | 37 | 0.2 | ∘ | x |
| | density | | | | |
| F | Large | 35 | 0.0 | | x |
| | density | | | | |

(Note 1:)
Evaluation of water repellent reads as follows.
: extremely well water-repellent.
∘: comparatively water-repellent.
x: not water-repellent.
(Note 2:)
Evaluation of leak reads as follows.
: Leak current is extremely small and gives rise to no problem as an insulating layer.
∘: Leak current is comparatively small and gives rise to no problem as an insulating layer.
Δ: Leak current is comparatively large but is barely usable as an insulating layer
x: Leak current is significant and not usable as an insulating layer.

When surface free energy becomes small, leak current tends to become large, and around 45 mN/m for surface free energy was a limit value that will not give rise to a problem. In this case, as for respective components of surface free energy, as the hydrogen bonding term becomes smaller, the leak current tends to become larger, and around 2.0 mN/m for hydrogen bonding term is a limit value that will not give rise to a problem. In addition, all the insulating layers that have not given rise to any problem with leak current contained no alkyl group. On the other hand, an insulating layer having a low surface free energy gave rise to a problem with leak current, but in order to strike electrodes differently by way of patterning of surface free energy, surface free energy needs to be sufficiently low and around 40 mN/m was the limit. At this time, the hydrogen bonding term decreases as surface free energy becomes low, and in order to strike electrodes differently by way of patterning of surface free energy, around 1.0 mN/m for hydrogen bonding term was the limit and the lower than this was desirable. Materials having a low surface free energy contained alkyl groups, and by increase in the alkyl groups, surface free energy decreased and the hydrogen bonding term tended to decrease. The surface free energy for materials with the least alkyl group density was 40 mN/m, and the hydrogen bonding term thereof was 1.0 mN/m.

As described above, a preferable example of an organic transistor in the present invention is stipulated to be a double structure consisting of an insulating layer with 40 mN/m or less and an insulating layer with 45 mN/m or more for surface free energy, a double structure consisting of an insulating layer with 1.0 mN/m or less and an insulating layer with 2.0 mN/m or more for a hydrogen bonding term of surface free energy, and moreover, a double structure consisting of an insulating layer containing an alkyl group in a side chain and an insulating layer containing no alkyl group, in channel portions having undergone no change in structure with UV light. In addition, for striking gate electrodes differently, in the gate portions, a substrate insulating layer provided between a substrate and a gate electrode derives surface free energy of 40 mN/m or less and hydrogen bonding term of surface free energy is stipulated to be 1.0 mN/m or less.

(Experiment 2)

Surface free energy of an insulating layer consisting of polyimide containing an alkyl group in a side chain was caused to undergo partial change, and an experiment on striking water droplets differently was implemented with an ink-jet method. Onto a portion of an insulating layer with surface free energy being sufficiently low and showing an initial contact angle of 95 degrees which was subjected to irradiation of UV light to partially increase surface free energy and decrease the contact angle, water droplets were made to drop by an ink-jet method, and it was determined whether or not the droplets after landing went over a portion having a low surface free energy. Table 2 shows a result thereof. Table 2 shows relationship between contact angle of water of polyimide after 254 nm UV light irradiation and the state of striking droplets differently, to be applied to description of an experiment of the present invention.

TABLE 2

| | Contact angle of water | | | | | | | | |
|---|---|---|---|---|---|---|---|---|---|
| | (subject to UV irradiation) | | | | | | | | |
| | 10° | 20° | 30° | 40° | 50° | 60° | 10° | 80° | 90° |
| State of striking | | | | ∘ | ∘ | Δ | x | x | x |
| droplets differently | | | | | | | | | |

As shown in Table 2, in case of contact angle of water in the UV light irradiated portion being not more than 30 degrees, they stopped completely in the portion having a low surface free energy so as to allow different strokes sufficiently (in the table). Even 40 degrees and 50 degrees allowed to strike differently, but the case of droplets to go beyond after landing occurred (∘ in the table). With 60 degrees, the case of droplets to go beyond after landing increased, but there was a case where differentiation of striking was barely feasible (Δ in the table), and with not less than 70 degrees almost all droplets went beyond the portion having a low surface free energy (x in the Table). Accordingly, 60 degrees or less of contact angle of water is set as a limit that can stop the droplets after landing.

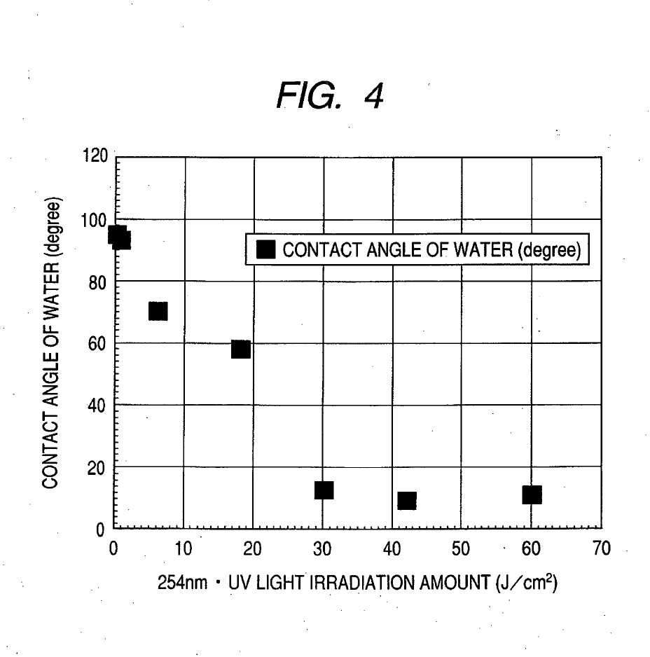

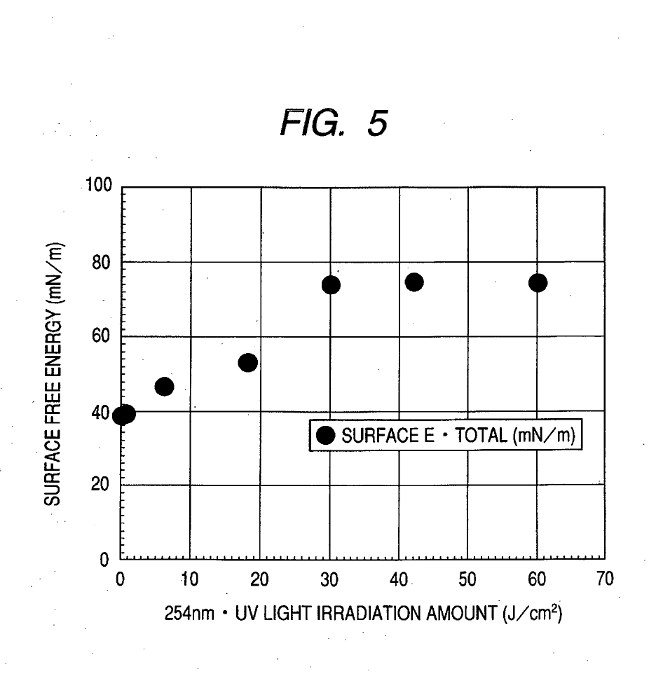

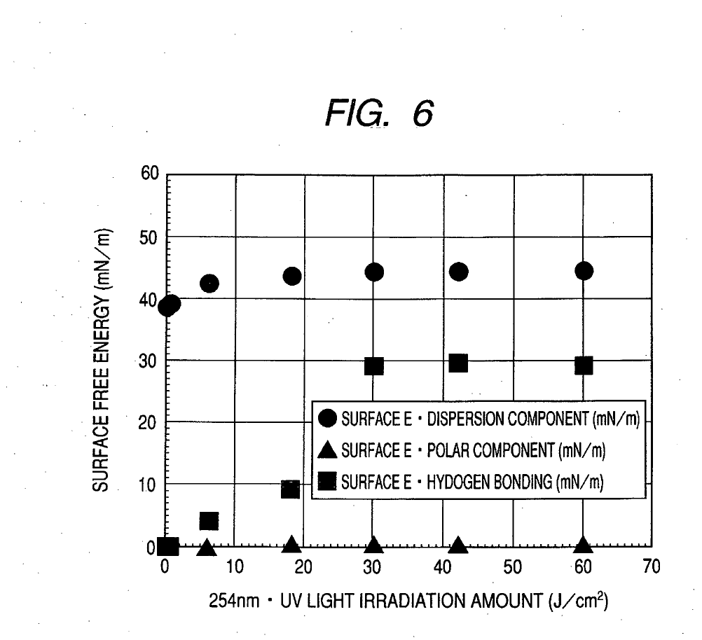

Accordingly, 60 degrees or less of contact angle of water is set as a limit that can stop the droplets after landing. 254 nm UV light irradiation amount at the time when the contact angle of water becomes 60 degrees or less is approximately 10 J/cm² based on an extrapolated value as shown in FIG. 4, and surface free energy at this time is approximately 50 mN/m or more in total based on an extrapolated value as shown in FIG. 5 and approximately 5 mN/m or more in the hydrogen bonding term as shown in FIG. 6.

As described above, the surface free energy of an insulating layer in contact with source and drain electrodes and a gate electrode of an organic transistor in a preferable example of the present invention is defined as 50 mN/m or more and the hydrogen bonding term is defined as to be 5 mN/m or more.

(Experiment 3)

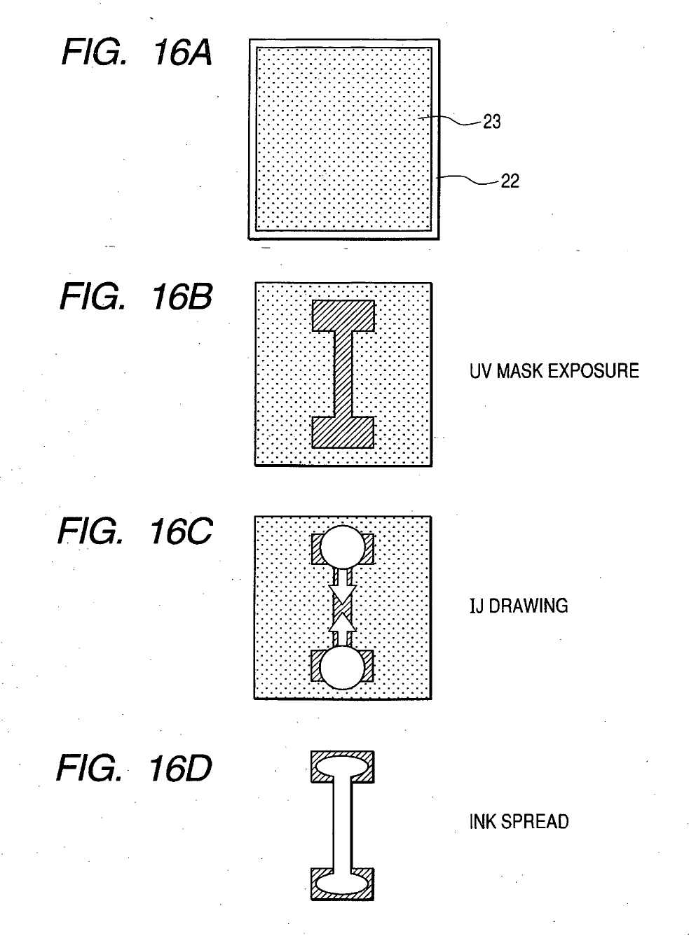

Based on a result of Experiments 1 and 2, a substrate insulating layer with surface free energy of 40 mN/m or less was subjected to patterning thereon with UV light to form a portion to become a gate electrode with surface free energy of 50 mN/m or more and to consider to what extent gate electrode width can be struck differently. Consideration was implemented with water as solvent. As in FIG. 16, a gate electrode portion of a substrate insulating layer-coating part 23 on a glass substrate 22 and, at the same time, portions sufficiently larger in width than the gate electrode on both sides of the gate electrode was subjected to UV exposure so as to make the surface free energy of the portions high to carry out patterning, and water was caused to drop with ink jet in the portions on both sides of the gate electrode. Since surface free energy in the portion to become the gate electrode is sufficiently high than its circumference, water soaks the gate electrode portion and spreads. When the gate electrode width was about 20 μm, patterning was sufficiently feasible, but as the gate electrode width became thinner, good patterning became less feasible. In the experiment, when it was up to around 3 μm, the dropped water soaked and spread, but when it was 1 μm, the dropped water could not soak and spread skillfully.

(Experiment 4)

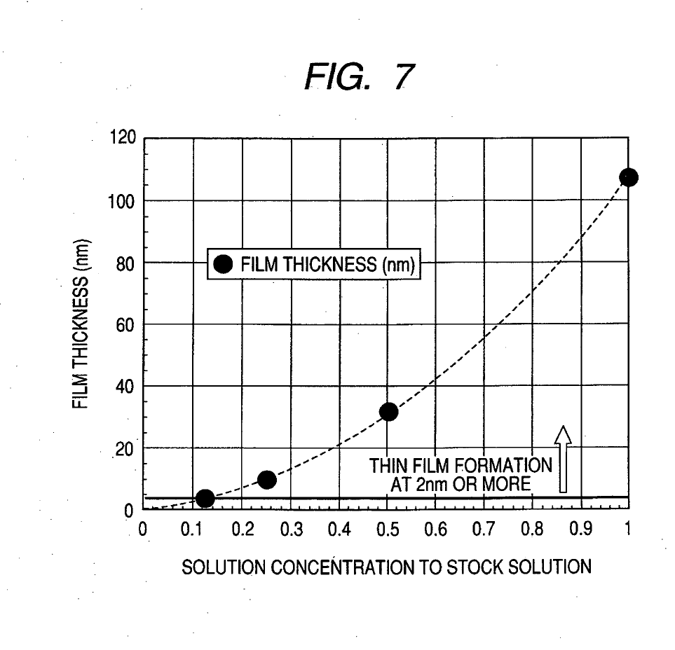

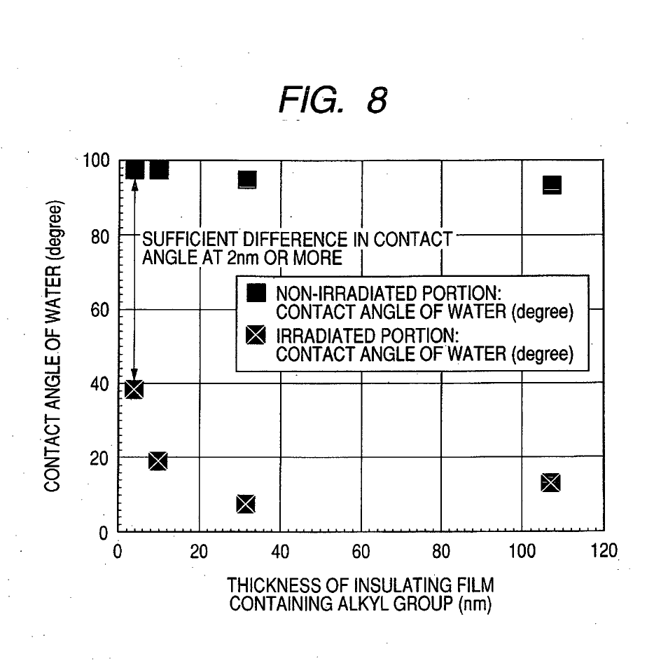

As shown in FIG. 7, as the concentration of polyimide was caused to decrease, the film thickness of an insulating layer made of polyimide containing an alkyl group in a side chain decreased, thereby a thin film could be formed up to 2 nm. In addition, as shown in FIG. 8, the insulating layer having undergone changes in film thickness was irradiated with 254 nm and 30 J/cm UV light, then also a sufficient contact angle of water at a film thickness of 2 nm could be observed. Based on this, the thickness of the insulating layer containing alkyl group in side chain is stipulated to be 2 nm or more that enables thin film formation.

In addition, as for the insulating layer made of polyimide containing no alkyl group in a side chain, as shown below in Table 3, in order to derive sufficient performance on insulating breakdown voltage, a film thickness of 100 nm or more was required.

Table 3 shows relationship between the film thickness of polyimide containing an alkyl group in a side chain and the breakdown voltage, to be applied to description of experiments of the present invention.

TABLE 3

| | Film thickness of Insulating layer | | | | | |
|---|---|---|---|---|---|---|
| | 50 nm | 100 nm | 200 nm | 300 nm | 400 nm | 500 nm |
| Insulating | No | Good | Good | Good | Good | Good |
| Breakdown | good | | | | | |
| Voltage | | | | | | |

In Table 3, “Good” means sufficient in practical use, and “No good” means insufficient in practical use.
(Experiment 5)

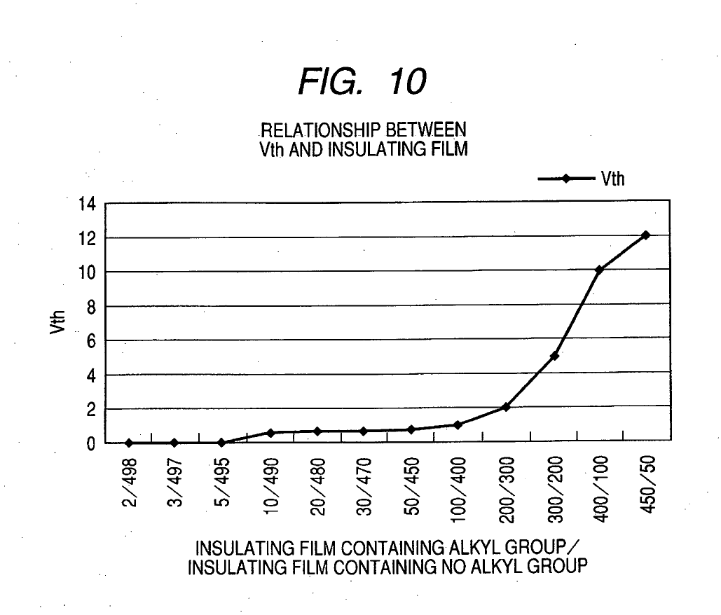

By changing the film thickness of an upper insulating layer made of polyimide containing an alkyl group in a side chain and a lower insulating layer polyimide containing no alkyl group, electric properties of TFT were evaluated. For a semiconductor layer, P3HT was used. Setting the total film thickness of the insulating film at 500 nm, proportion of the upper layer to the lower layer was changed. FIG. 10 shows relationship between the film thickness of respective insulating layers and Vth. It is apparent that the upper insulating layer made of polyimide containing an alkyl group in a side chain exceeds 200 nm, then Vth steeply becomes large. Next, showing embodiments, the present invention will be described in detail.

The present invention is to make an organic transistor having excellent functions, including an organic semiconductor layer, an insulating layer and a plurality of electrodes, wherein the insulating layer has a stacked body of an insulating layer made of polyimide containing an alkyl group in a side chain and an insulating layer made of polyimide containing no alkyl group. Composition of this stacked body of insulating layers may vary continuously in the film thickness direction, or may be a separated multi-layer structure.

The present embodiment exemplifies production of an excellent organic transistor having a staked body of an insulating layer made of polyimide containing an alkyl group in a side chain and an insulating layer made of polyimide containing no alkyl group.

Here, for the lower layer, without limiting to an insulating layer made of polyimide containing no alkyl group in the present embodiment, but a variety of insulating layers made of materials containing no alkyl group can be used. Disregarding whether materials in that case are organic or inorganic, all materials presenting insulation can be used, and in particular, in case of an organic system, polyimide, polyamide, polyamideimide and polyolefin containing no alkyl group, and for inorganic system, a highly insulating material such as SiO₂ and Ta₂O₅ are desired to be used.

In addition, as for an upper layer, instead of an organic insulating layer made of polyimide containing an alkyl group in a side chain, an insulating layer made of the other materials can be used as well. In that case, a material showing insulation, in particular with surface free energy being low, generating single axis alignment regulating force by rubbing treatment and polarized ultraviolet rays, and being caused to derive variations in surface free energy, and having bonding being destructible with ultraviolet rays in order to make mapping easy at the time of electrode drawing is preferably used. For example, organic system polymeric material such as polyimide, polyamide, polyamideimide and PVP (polyvinyl phenol) containing bonding being destructible by ultraviolet rays is desired to be used.

For forming a double layer structure of the gate insulating layer used in a preferable mode of the present invention, with variety of methods such as a spin coat method, an ink-jet drawing method, offset printing, screen printing and the like, it can be made easily. In addition, a gate electrode, source and drain electrodes can be formed with a variety of methods such as an ink-jet drawing method, a screen printing method. Any film forming method can make thin film sufficiently functionable in an organic transistor of the present invention.

The double insulating layer structure used in a preferable mode of the present invention is desired to be formed as thinner as possible within such a range that can retain insulation sufficiently from a knowledge on device properties. The insulating layer made of polyimide containing no alkyl group is desired to be about 1 μm or less in order to be used effectively with a low gate voltage. On the other hand, an insulating layer made of polyimide containing an alkyl group in a side chain is satisfactory if it has a sufficient thickness required for alignment regulating force and surface free energy patterning, 2 nm or more is desired which is formable as film. In addition, an insulating layer containing an alkyl group in a side chain is desired to be 200 nm or less in consideration of electric properties.

Moreover, as for an insulating layer in a double structure used in a preferable mode of the present invention, in consideration of its role, an insulating layer made of polyimide containing no alkyl group is required to be highly insulating, and therefore, an insulating layer made of polyimide containing no alkyl group is desired to be thicker than an insulating layer containing an alkyl group in side chain.

As for an organic semiconductor layer in the present invention, a variety of materials such as low-molecular system and polymeric system can be nominated, and any known material can be used, but a polymeric system semiconductor material such as P3HT (poly(3-hexylthiophene)) and F8T2 (Fluorene-bithiophene) and the like in particular is comparatively easily soluble with an organic solvent and easily undergoes drawing with an ink-jet method, and is arranged in a single axis direction, whereby its improvement in properties can be expected and suitable for use in a process of the present invention. In addition, low-molecular material such as pentacene, rubrene and porphyrin showing high mobility in the case where hopping conduction is main and molecules are arranged perpendicularly also dissolves by causing precursor solution to dissolve into an organic solvent or by treating the low molecules themselves with a special organic solvent, and can be used in the process of the present invention.

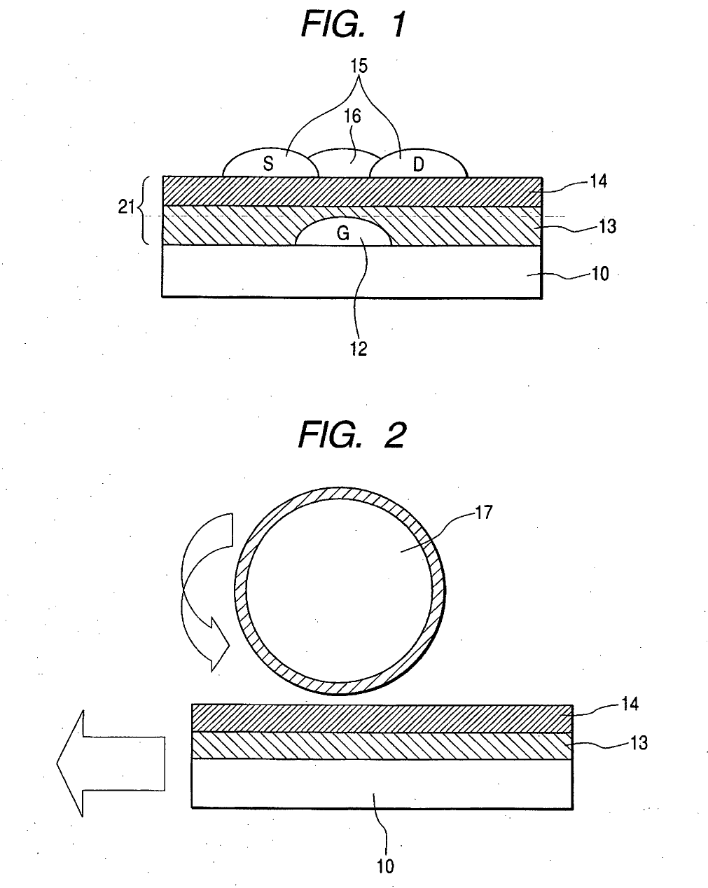

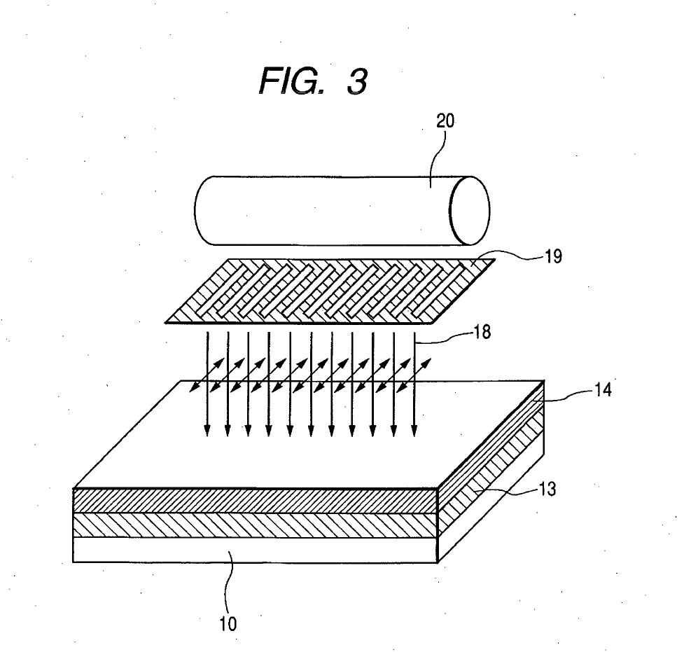

With referring to the drawings, an organic transistor provided with a double insulating layer structure consisting of an organic insulating layer made of polyimide containing an alkyl group in a side chain and an insulating layer made of polyimide containing no alkyl group will be described briefly as a preferable example of the present invention. FIG. 1 is a sectional diagram of an embodiment of an organic transistor structure of a bottom gate type showing the present invention. As shown in FIG. 1, a gate electrode 12 is formed only in a portion on a substrate 10. Thereon, an insulating layer 13 made of polyimide containing no alkyl group is formed, and thereon an insulating layer 14 made of polyimide containing an alkyl group in side chain is formed. Thereon, source and drain electrodes 15 are particularly stacked at a distance of the channel length, and moreover an organic semiconductor layer 16 is partially formed so as to cover the channel part. Reference numeral 21 denotes a gate insulating film consisting of the insulating layer 13 and the insulating layer 14. FIG. 2 is an explanatory diagram showing a rubbing treatment method of giving alignment regulating force. FIG. 3 is a conceptual diagram of polarized UV light irradiation of giving alignment regulating force. As follows, another embodiment of the present invention will be described.

The present embodiment is to make an organic transistor having excellent functions, including a substrate, a substrate insulating layer, a gate electrode, a gate insulating layer, source and drain electrodes and an organic semiconductor layer, wherein the gate insulating layer is a stacked body of an insulating layer made of polyimide containing an alkyl group in a side chain and an insulating layer made of polyimide containing no alkyl group. Composition of this stacked body of gate insulating layer may vary in a continuous fashion in the film thickness direction, or may be a separated multi-layer structure.

The present embodiment exemplifies production of an organic transistor having excellent functions, including an insulating layer made of polyimide containing an alkyl group in a side chain for a substrate insulating layer, and, for a gate insulating layer, a stacked body of an insulating layer made of polyimide containing an alkyl group in a side chain and an insulating layer made of polyimide containing no alkyl group.

Forming of a substrate insulating layer and a double layer structure of the gate insulating layer in the present embodiment can be made easily by a variety of methods such as a spin coat method, an ink-jet drawing method, offset printing screen printing and the like. In addition, a gate electrode, source and drain electrodes can be formed by a variety of methods such as an ink-jet drawing method and a screen printing method. Any film forming method can make thin film sufficiently functionable in an organic transistor of the present invention.

The substrate insulating layer in the present embodiment may be provided with any thickness, but the thickness is desired to such an extent that will not deteriorate flexibility of a device. In addition, a double layer structure of the gate insulating layer of the present invention is desired to be formed as thinner as possible within such a range that can retain insulation sufficiently from a knowledge on device properties. The insulating layer made of polyimide containing no alkyl group is desired to be around 1 μm or less in order to be used effectively with the gate voltage being a low voltage. On the other hand, an insulating layer made of polyimide containing an alkyl group in a side chain is satisfactory if it has a sufficient thickness required for alignment regulating force and surface free energy patterning, and the thickness is desired to be 2 nm or more which is formable as film. In addition, an insulating layer made of polyimide containing an alkyl group in a side chain is desired to be 200 nm or less in consideration of electric properties.

Moreover, as for a gate insulating layer in a double structure in the present invention, in consideration of its role, an insulating layer made of polyimide containing no alkyl group is required to be highly insulating, and therefore, an insulating layer made of polyimide containing no alkyl group is desired to be thicker than an insulating layer made of polyimide containing an alkyl group in side chain.

Other points are likewise the above-described embodiment.

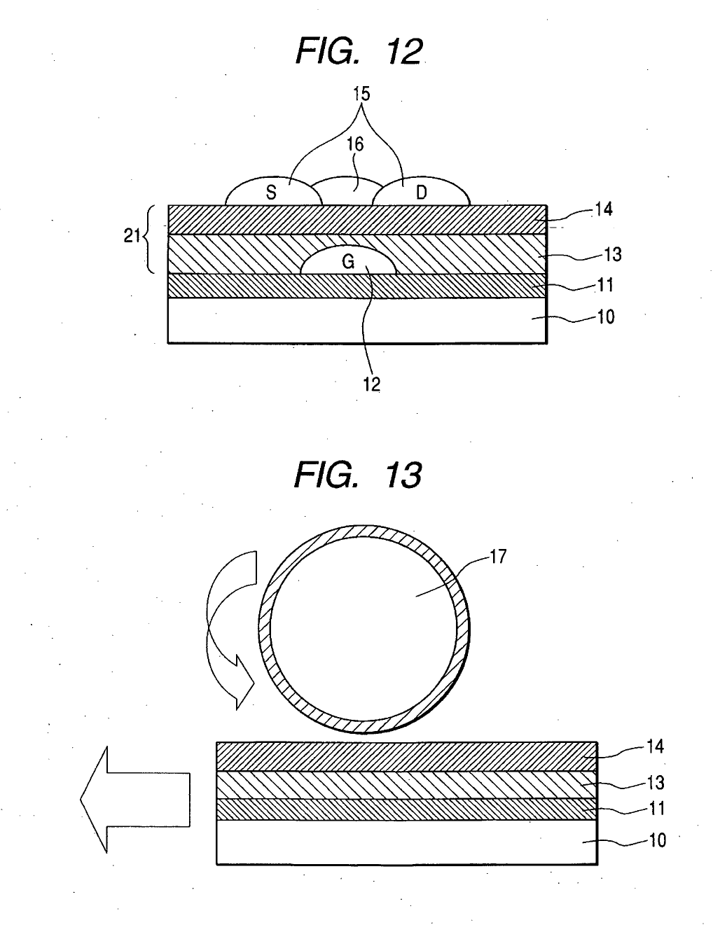

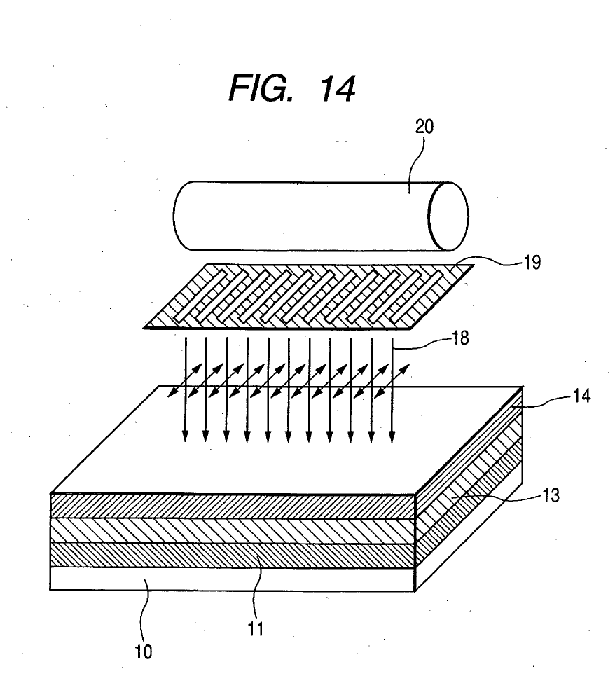

With referring to the drawings, an organic transistor, in the present invention, provided with a substrate insulating layer of an organic insulating layer made of polyimide containing an alkyl group in a side chain, and provided with a double layer structure of the gate insulating layer consisting of an organic insulating layer made of polyimide containing an alkyl group in a side chain and an insulating layer made of polyimide containing no alkyl group will be described briefly. FIG. 12 is a sectional diagram of an embodiment of an organic transistor structure of a bottom gate type showing the present invention. As shown in FIG. 12, a substrate insulating layer 11 made of polyimide containing an alkyl group is provided on a substrate 10, and thereon a gate electrode 12 is formed only in a portion. Thereon, a gate insulating layer 13 made of polyimide containing no alkyl group is formed, and thereon a gate insulating layer 14 made of polyimide containing an alkyl group in a side chain is formed. Thereon, source and drain electrodes 15 are particularly stacked at a distance of the channel length, and moreover an organic semiconductor layer 16 is partially formed so as to cover the channel part. FIG. 13 is an explanatory diagram showing a rubbing treatment method of giving alignment regulating force, and FIG. 14 is a conceptual diagram of polarized UV light irradiation of giving alignment regulating force.

With referring to the following examples, the present invention will be described further particularly.

### EXAMPLE 1

An example of having employed an ink-jet drawing method as a method of forming source and drain as well as an organic semiconductor layer to make a bottom gate type organic transistor provided with a double insulating layer structure consisting of an insulating layer made of polyimide containing an alkyl group in a side chain and an insulating layer made of polyimide containing no alkyl group will be nominated.

On a glass substrate, Al for forming a gate was formed, which underwent patterning with a photolitho process to form a gate electrode. Thereon, polyimide (SE812 produced by NISSAN CHEMICAL INDUSTRIES, LTD.) was coated with a spinner to obtain a thickness of approximately 300 nm and underwent firing with 300° C. for 30 minutes to form an insulating layer made of polyimide containing no alkyl group. Hereon, as an insulating layer containing an alkyl group in a side chain, polyimide containing a side chain of an alkyl group with low surface energy was formed with offset printing to obtain a thickness of 30 nm and underwent firing with 210° C. with an oven for 60 minutes. After forming a double insulating layer structure, in a rubbing apparatus as shown in FIG. 2, with a rubbing roller made of cotton, rubbing treatment at 1000 rpm and orientation treatment were implemented.

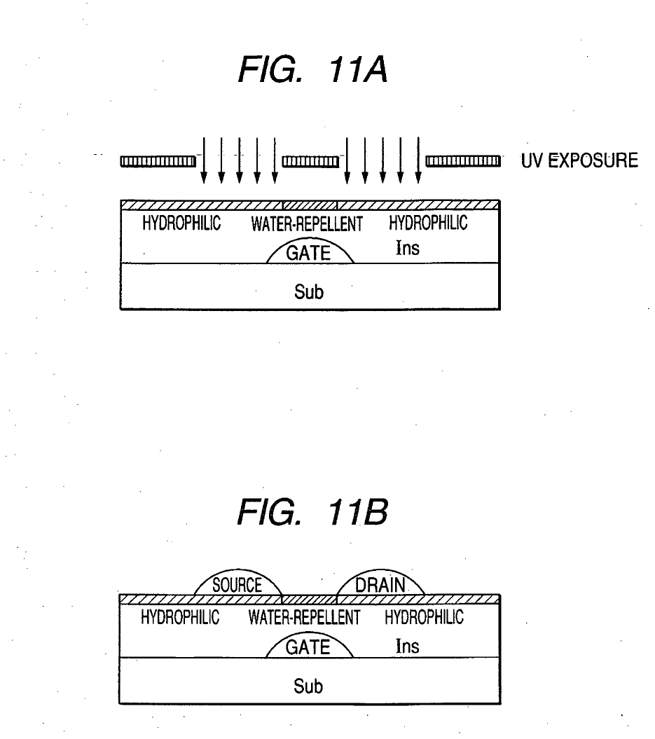

After rubbing was over, the substrate was cleansed, and subsequently the surface of polyimide containing an alkyl group in a side chain underwent masking with a metal mask, and the portion where a channel was desired to be formed as in FIG. 11 underwent pattern exposure across the 5 μm width with an aligner (UX3000 produced by USHIO INC.) with Deep UV light of 254 nm. Implementing exposure with 254 nm UV light, polyimide incurs significant changes in surface energy. In particular, polyimide containing an alkyl group in a side chain with a low surface free energy incurs significant changes thereof.

FIGS. 5 and 6 show relationship between the 254 nm UV light irradiation amount and the surface free energy of polyimide containing an alkyl group in a side chain. According to UV light irradiation amounts, hydrogen bonding term in particular increases by large margin. FIG. 4 shows relationship between the 254 nm UV light irradiation amount and the contact angle of water. By UV light irradiation as shown in FIG. 4, the contact angle of water varies from 95 degrees to 10 degrees.

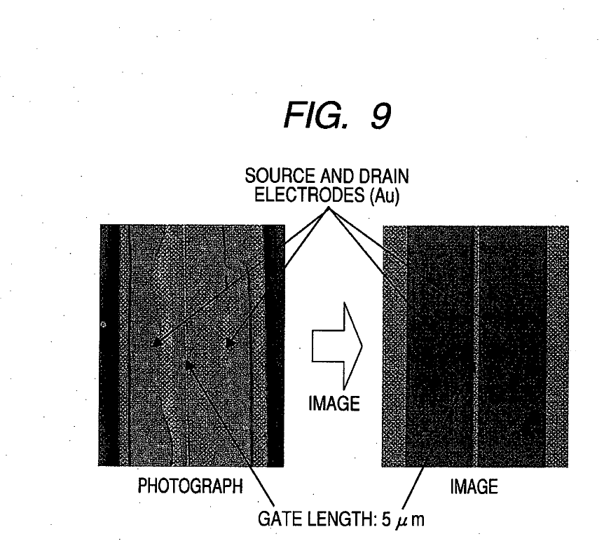

Shielding only the portion for forming a channel with a mask, exposure with 254 nm UV light was implemented, and thereafter, source and drain electrodes were formed with an ink-jet drawing method. For an electrode material, the one with gold nano particles having been dispersed in a solution of an acqueous system was used (hereinafter to be referred to as “gold nano ink”), and when this solution was coated onto both sides of polyimide with low surface energy to become a channel by ink-jet drawing, the gold nano ink was dammed with polyimide to become a channel since surface energy was 38 mN/m that was extremely low, soaked/spread in both sides of the upper layer and was stabilized. FIG. 9 shows a photograph after gold nano ink was brought into drawing with an ink-jet method. As in FIG. 9, it is apparent that, even with 5 μm channel length, gold nano ink to become source and drain spreads in both sides of a channel and the channel is formed beautifully.

Under this state, implementing firing with 210° C. with an oven for 120 minutes, gold nano particles for forming source and drain were fused themselves with each other and metalized to form electrodes. Subsequently, on polyimide with low surface energy to become a channel, as a semiconductor layer, a porphyrin precursor, which was dissolved into a toluene solvent, was jetted for drawing with an ink jet method, underwent firing with 200° C. with an oven for 60 minutes and was crystallized. Film thickness of the semiconductor layer was set at 100 nm. An orientation state of the semiconductor film was confirmed with a polarized microscope to note that bright and dark difference appeared and orientation in a direction of rubbing was derived. In addition, channel length was 5 μm. Moreover, the same polyimide as the one used for the insulating layer was formed thereon as a protection film of 500 nm with spin coating and underwent firing with 250° C. with an oven for 60 minutes.

Wiring was implemented in the gate and the source and drain on the formed organic transistor of a bottom gate type. Measurement on properties of the formed organic transistor with a semiconductor parameter analyzer in a vacuum showed high mobility in the order of 0.2 cm²/Vs and good saturation characteristic to the gate voltage.

### EXAMPLE 2

Except that, as the lower insulating layer on the Al gate wiring, polyimide was replaced with SiO₂ of plasma CVD, a bottom gate type organic transistor was made likewise Example 1. Film forming conditions of SiO₂ were set at TEOS/He/O₂=185 sccm/100 sccm/3500 sccm, reaction pressure of 800 mtorr, substrate temperature of 330° C. and film thickness of 300 nm.

Measurement on properties of the formed organic transistor with a semiconductor parameter analyzer in a vacuum showed a mobility of 0.3 cm²/Vs.

In the present example, a glass substrate is used, but all the other inorganic system materials such as a Si substrate can be used. In addition, polymeric system materials may be used, and, in particular, liquid crystal polymer and the like are suitable to an organic transistor of the present invention due to its nature of thermal expansion and high heat resistance.

In the present example, Al is used as a gate electrode material, and a gate electrode is formed with photolithography, but an electrically conductive metal material can be formed by an ink-jet method or a screen printing method to implement printing directly onto a required places. As the electrically conductive metal material, low temperature firing type Ag nano ink or nano paste in use of Ag nano particles or low temperature firing type Ag ink or paste in mixture of silver oxide and organic silver compounds utilizing occurrence of oxidation-reduction reaction of Ag at 150° C. are nominated. These materials show sufficient low resistance similar to metal Ag after firing with 150° C. for around 60 minutes and are desirable as materials at the time of forming a gate electrode with printing process such as an ink-jet method or a screen printing method. In addition, besides Ag, there may be used low temperature type electrically conductive ink or paste by use of all electrically conductive materials capable of undergoing low temperature firing with nano particle formation of Au, Pt and the like.

In the above-described two examples, polyimide and SiO₂ are used for an insulating layer containing no alkyl group, but inorganic system insulating materials such as Al₂O₃ and Ta₂O₅ can also be used. In addition, in the present invention, SiO₂ undergoes film formation under vacuum, but a method of coating inorganic system coating type insulating film by spin coating, offset printing or the like and firing it can be used. In addition, as organic system insulating material, polyamide, polyamideimide and the like besides polyimide can be coated by spin coating, offset printing, etc, are highly insulating with low leak current and are usable.

In the present example, in order to arrange organic semiconductor layers, the polyimide film containing an alkyl group in a side chain undergoes rubbing, but organic semiconductor layers can also be arranged by using polarized ultraviolet ray equipment as shown in FIG. 3 to irradiate polarized ultraviolet rays onto the polyimide film. Polyimide film incurs a cleavage in imide structure of the main chain skeleton by ultraviolet rays, and therefore irradiation of polarized ultraviolet rays causes imide structure to remain in the bias direction of light to generate alignment regulating force in one direction. Irradiating polarized ultraviolet rays onto film of polyimide containing an alkyl group in a side chain subject to source and drain electrodes formation, organic semiconductor layers formed onto polyimide film will become arrangeable in one direction.

In addition, in the present example, a solution obtained by dispersing gold nano particles into an electrically conductive material of source and drain electrodes is used, but nano particle dispersed solutions which include any highly electrically conductive metals, such as Pt, which can be shrunk down to nano size to undergo low temperature firing, can also be used. In addition, organic system electrically conductive materials such as PEDOT•PSS solution capable of being brought into coating with ink-jet drawing can be used.

In the present example, porphyrin is used for semiconductor layers, but soluble precursor of low molecule semiconductor material of pentacene and rubrene or low molecule semiconductor materials that are soluble themselves can be used. In case of a low molecule system material, hopping conduction is main, and with molecules being perpendicular to a substrate, overlapping of π electrons results in increase in probability in electron hopping and conductivity tends to increase further. On the other hand, as an organic semiconductor material of a polymeric system P3HT, F8T2, etc. can be used, but will give rise to effects a little bit smaller than the materials of a low molecule system from the point of view of orientation.

### COMPARATIVE EXAMPLE 1

Except that an insulating layer made of polyimide containing no alkyl group was not provided on a substrate, a bottom gate type organic transistor was made likewise Example 1. On a glass substrate, Al for forming a gate was formed, which underwent patterning with a photolitho process to form a gate electrode. Thereon, polyimide containing an alkyl group in a side chain with low surface free energy (preproduction sample) was formed with offset printing to derive 300 nm and underwent firing with 210° C. with an oven for 60 minutes. After forming a double insulating layer structure with a rubbing roller made of cotton, rubbing treatment was implemented at 1000 rpm and orientation treatment was implemented.

After rubbing was over, the substrate was cleansed, and subsequently the surface of polyimide containing an alkyl group in a side chain underwent masking with a metal mask, and the portion where a channel was desired to be formed underwent pattern exposure across the 5 μm width with an aligner with Deep UV light of 254 nm. Shielding only the portion to become a channel with a mask, exposure with 254 nm UV light was implemented, and thereafter, source and drain electrodes were formed with an ink-jet drawing method. For an electrode material, the one with gold nano particles having been dispersed in a solution of an acqueous system was used, and when this solution was coated onto both sides of polyimide with low surface energy to become a channel with ink-jet drawing, the gold nano ink was dammed with polyimide to become a channel since surface energy was 38 mN/m that was extremely low, soaked/spread in both sides of the surface layer and was stabilized, under the state of which, implementing firing with 210° C. with an oven for 120 minutes, gold nano particles to become source and drain were fused themselves with each other and metalized to form electrodes.

Subsequently, on polyimide with low surface energy to become a channel, as a semiconductor layer, a toluene solution of a porphyrin precursor was formed to derive 100 nm with ink jet drawing, underwent firing with 200° C. with an oven for 60 minutes and was crystallized. Moreover, a protection film was formed with spin coating and underwent firing with 200° C. with an oven for 60 minutes.

Wiring was implemented in the gate and the source and drain on the formed organic transistor of a bottom gate type. As the result of measurement on properties of the formed organic transistor with a semiconductor parameter analyzer in a vacuum, the organic transistor having a large leak current and sufficient transistor properties were not obtained.

### COMPARATIVE EXAMPLE 2

Except that polyimide of orientated film did not undergo rubbing, a bottom gate type organic transistor was made likewise Example 1. An orientation state of the semiconductor film was confirmed with a polarized microscope to note that bright and dark difference appeared but a minute particle state was observed and no orientation was confirmed.

Measurement on properties of the formed organic transistor with a semiconductor parameter analyzer in a vacuum showed a mobility of 0.03 cm²/Vs.

### EXAMPLE 3

An example of having employed an ink-jet drawing method as a method of forming gate electrode, source and drain electrodes as well as an organic semiconductor layer to make a bottom gate type organic transistor provided with, as a substrate insulating layer, an insulating layer made of polyimide containing an alkyl group in a side chain and provided with, as a gate insulating layer, a double insulating layer structure consisting of an insulating layer made of polyimide containing an alkyl group in a side chain and an insulating layer made of polyimide containing no alkyl group will be nominated.

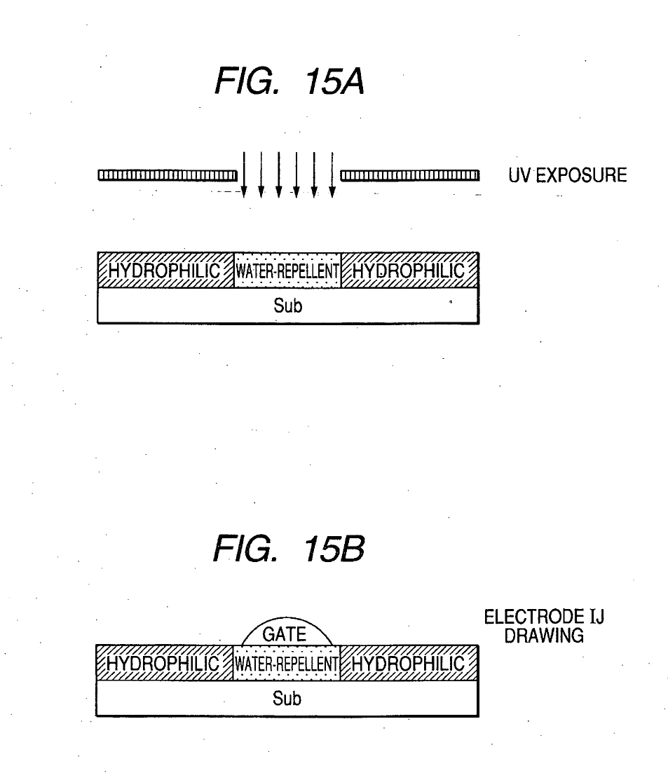

On a glass substrate, polyimide containing a side chain of an alkyl group with low surface energy was formed with spin coating to obtain a thickness of 30 nm and underwent firing with 210° C. with an oven for 60 minutes. Subsequently the surface of polyimide containing an alkyl group in a side chain underwent masking with a photo mask, and the portion where a gate was desired to be formed as in the sectional drawing of FIG. 15 underwent pattern exposure across 20 μm width of the gate electrode and 1.5 mm length of the gate electrode with an aligner (UX3000 produced by USHIO INC.) with Deep UV light of 254 nm. Implementing exposure with 254 nm UV light, polyimide incurs significant changes in surface energy. In particular, polyimide containing an alkyl group in a side chain with surface free energy being low incurs significant changes thereof.

FIGS. 5 and 6 show relationship between the 254 nm UV light irradiation amount and the surface free energy of polyimide containing an alkyl group in a side chain. According to UV light irradiation amounts, particularly hydrogen bonding term increases by large margin. FIG. 4 shows relationship between 254 nm UV light irradiation amount and contact angle of water in the same polyimide material. By UV light irradiation as shown in FIG. 4, the contact angle of water varies from 95 degrees to 10 degrees.

Shielding the portions other than the portion to become a gate with a mask, the portion to become the gate underwent exposure with 254 nm UV light, and thereafter, the gate electrode was formed with an ink-jet drawing method. For an electrode material, the one with gold nano particles having been dispersed in a solution of an acqueous system was used (hereinafter to be referred to as “gold nano ink”), and the gold nano ink was coated onto the polyimide with low surface energy to become a gate with ink-jet drawing as shown in FIG. 16, the gold nano ink soaked/spread over the surface of the polyimide to become a gate since surface energy was 38 mN/m that was extremely low, and uniformly spread only over the gate portion since surface free energy in the circumference of the gate was held low, and was stabilized.

Under this state, implementing firing with 210° C. with an oven for 120 minutes, gold nano particles to become a gate electrode were fused themselves with each other and metalized to form an electrode. On this gate electrode, polyimide (SE812 produced by NISSAN CHEMICAL INDUSTRIES, LTD.) was coated with a spinner to obtain thickness of approximately 300 nm and underwent firing with 300° C. for 30 minutes to form a gate insulating layer containing no alkyl group. Hereon, as a gate insulating layer containing an alkyl group in a side chain, polyimide containing an alkyl group in a side chain with low surface energy (preproduction sample) was formed with offset printing to derive 30 nm and underwent firing with 210° C. with an oven for 60 minutes.

After forming the double layer structure of the gate insulating layer, in a rubbing apparatus as shown in FIG. 13, with a rubbing roller made of cotton, rubbing treatment was implemented at 1000 rpm and orientation treatment was implemented. After rubbing was over, the substrate was cleansed, shielding only the portion to become a channel with a mask, exposure with 254 nm UV light was implemented, and thereafter, source and drain electrodes were formed with an ink-jet drawing method. For an electrode material, gold nano particle ink was used, and when this solution was coated onto both sides of polyimide with low surface energy to become a channel with ink-jet drawing, the gold nano ink was dammed with polyimide to become a channel since surface energy was 38 mN/m that was extremely low, soaked/spread in both sides of the upper layer and was stabilized. Under this state, implementing firing with 210° C. with an oven for 120 minutes, gold nano particles to become source and drain were fused themselves with each other and metalized to form electrodes.

Subsequently, on polyimide with low surface energy to become a channel, as a semiconductor layer, a porphyrin precursor, which was dissolved into a toluene solvent, was brought into drawing with ink jet, underwent firing with 200° C. with an oven for 60 minutes and was crystallized. Film thickness of the semiconductor layer was set to 100 nm. An orientation state of the semiconductor film was confirmed with a polarized microscope to note that bright and dark difference appeared and orientation in a direction of rubbing was derived. In addition, channel length was 5 μm. Moreover, the same polyimide as the one used for the insulating layer was formed thereon as a protection film of 500 nm with spin coating and underwent firing with 250° C. with an oven for 60 minutes.

Wiring was implemented in the gate and the source and drain on the formed organic transistor of a bottom gate type. Measurement on properties of the formed organic transistor with a semiconductor parameter analyzer in a vacuum showed a high mobility in the order of 0.2 cm²/Vs and a good saturation characteristic to the gate voltage.

### EXAMPLE 4

Except that, as the lower layer insulating film on the gate wiring, polyimide was replaced with SiO₂ of plasma CVD, a bottom gate type organic transistor was made likewise Example 1. Film forming conditions of SiO₂ were set at TEOS/He/O₂=185 sccm/100 sccm/3500 sccm, reaction pressure of 800 mtorr, substrate temperature of 330° C. and film thickness of 300 nm.

Measurement on properties of the formed organic transistor with a semiconductor parameter analyzer in a vacuum showed a mobility of 0.3 cm²/Vs.

For the present embodiment, a glass substrate is used, but all the other inorganic system materials such as a Si substrate can be used. In addition, polymeric system materials may be used, and in particular liquid crystal polymer and the like are suitable to an organic transistor of the present invention due to its nature of thermal expansion and high heat resistance.

In the present embodiment, Au is used as a gate electrode material, and Au nano ink undergoes printing directly onto required places by an ink-jet method to form a gate electrode, and as the electrically conductive metal material, low temperature firing type Ag nano ink in use of Ag nano particles or low temperature firing type Ag ink etc. in mixture of silver oxide and organic silver compounds utilizing occurrence of oxidation-reduction reaction of Ag at 150° C. are also nominated. These materials show a sufficiently low resistance similar to metal Ag after firing with 150° C. for around 60 minutes and are desirable as materials at the time of forming a gate electrode by printing process such as an ink-jet method or a screen printing method. In addition, besides Au and Ag, there may be used low temperature type electrically conductive ink or paste in use of all electrically conductive materials capable of undergoing low temperature firing by nano particle forming of Pt and the like.

In the above-described two embodiments, the two kinds of polyimide and SiO₂ are used for an insulating layer containing no alkyl group, but inorganic system insulating materials such as Al₂O₃ and Ta₂O₅ can also be used. In addition, in the present invention, SiO₂ undergoes film forming with vacuum film forming, but a method of coating an inorganic system coating type insulating film by spin coating, offset printing, etc. and undergoing firing can be used. In addition, as organic system insulating material, polyamide, polyamideimide and the like besides polyimide can be coated by spin coating, offset printing or the like are highly insulating with low leak current and are usable.

In the present embodiment, in order to arrange organic transistor layers, the polyimide film containing an alkyl group in a side chain undergoes rubbing, but organic transistor semiconductor layers can also be arranged by using polarized ultraviolet ray equipment as shown in FIG. 14 to irradiate polarized ultraviolet rays onto the polyimide film. Polyimide film incurs a cleavage in the imide structure of the main chain skeleton by ultraviolet rays, and therefore irradiation of polarized ultraviolet rays causes the imide structure to remain in the bias direction of light to generate alignment regulating force in one direction. After source and drain electrodes formation, irradiation of polarized ultraviolet rays onto film of polyimide containing an alkyl group in a side chain makes it possible to arrange organic transistor layers formed on a polyimide film in one direction.

In addition, in the present embodiment, a solution derived by dispersing gold nano particles into electrically conductive material of source and drain electrodes is used, but nano particle dispersed solutions which include any highly electrically conductive metals, such as Pt, which can be shrunk down to nano size to undergo low temperature firing, can also be used. In addition, organic system electrically conductive materials such as PEDOT•PSS solution capable of being brought into coating with ink-jet drawing can be used.

In the present embodiment, porphyrin is used for semiconductor layers, but soluble precursor of low molecule semiconductor material of pentacene and rubrene or low molecule semiconductor materials that are soluble themselves can be used. In case of low molecule system material, hopping conduction is main, and with molecules being perpendicular to a substrate, overlapping of π electrons results in increase in probability in electron hopping and conductivity tends to increase further. On the other hand, as an organic semiconductor material of a polymeric system P3HT, F8T2, etc. can be used, but will give rise to effects a little bit smaller than the materials of a low molecule system from the point of view of orientation.

### COMPARATIVE EXAMPLE 3

Except that an insulating layer containing an alkyl group was not provided as a substrate insulating layer on a substrate, a bottom gate type organic transistor was made likewise Example 3. On a glass substrate, Au ink for forming a gate was directly brought into drawing with ink jet, and a gate electrode was formed. Due to lack of the substrate insulating layer containing an alkyl group and of patterning of surface free energy, Au ink did not soak/spread, giving rise to dot shapes in size of around 30 μm connected in a sequential fashion, and height fluctuated significantly and never became constant. Under this state, implementing firing with 210° C. with an oven for 120 minutes, gold nano particles to become a gate electrode were fused themselves with each other and metalized to form an electrode.

On this gate electrode, polyimide (SE812 produced by NISSAN CHEMICAL INDUSTRIES, LTD.) was coated with a spinner to derive thickness of approximately 300 nm and underwent firing with 300° C. for 30 minutes to form a gate insulating layer containing no alkyl group. Hereon, as a gate insulating layer containing an alkyl group in a side chain, polyimide containing an alkyl group in a side chain with low surface energy (preproduction sample) was formed with offset printing to derive 30 nm and underwent firing with 210° C. with an oven for 60 minutes. After forming a double layer structure of the gate insulating layer, in a rubbing apparatus as shown in FIG. 13, with a rubbing roller made of cotton, rubbing treatment was implemented at 100 rpm and orientation treatment was implemented. After rubbing was over, the substrate was cleansed, shielding only the portion to become a channel with a mask, exposure with 254 nm UV light was implemented, and thereafter, source and drain electrodes were formed with an ink-jet drawing method. For an electrode material, gold nano particle ink was used, and when this solution was coated onto both sides of polyimide with low surface energy to become a channel by ink-jet drawing, the gold nano ink was dammed with polyimide to become a channel since surface energy was 38 mN/m that was extremely low, soaked/spread in both sides of the upper layer and was stabilized. Under this state, implementing firing with 210° C. with an oven for 120 minutes, gold nano particles to become source and drain were fused themselves with each other and metalized to form electrodes.

Subsequently, on polyimide with low surface energy to become a channel, as a semiconductor layer, a porphyrin precursor, which was dissolved into a toluene solvent, was brought into drawing with ink jet, underwent firing with 200° C. with an oven for 60 minutes and was crystallized. Film thickness of the semiconductor layer was set to 100 nm. An orientation state of the semiconductor film was confirmed with a polarized microscope to note that bright and dark difference appeared and orientation in a direction of rubbing was derived. In addition, channel length was 5 μm. Moreover, the same polyimide as the one used for the insulating layer was formed thereon as a protection film of 500 nm with spin coating and underwent firing with 250° C. with an oven for 60 minutes.

Wiring was implemented in the gate and the source and drain on the formed organic transistor of a bottom gate type. Properties of the formed organic transistor with a semiconductor parameter analyzer in a vacuum were measured, but since width and height of the gate electrode fluctuated significantly and were not constant, no constant electric field could be applied, and stable transistor properties were not derived.

An organic transistor of the present invention can realize as a highly reliable transistor with a high breakdown voltage and a low leak current and high performance, and therefore can be utilized to electronic devices such as a paper-like display, an organic ID tag, an organic EL, etc.

This application claims priority from Japanese Patent Application No. 2004-319737 filed on Nov. 2, 2004, which is hereby incorporated by reference herein.

What is claimed is:

1. An organic transistor having a bottom gate structure, comprising a substrate, a gate electrode, a gate insulating layer, source and drain electrodes and an organic semiconductor layer, wherein the gate insulating layer has a low surface energy in a portion thereof in proximity to the source and drain electrodes, and a relatively high surface energy in a portion thereof in proximity to the gate electrode, and has different compositions in a layer thickness direction.

2. The organic transistor according to claim 1, wherein the gate insulating layer has a double layer structure composed of an upper layer having a relatively low surface energy and a lower layer having a relatively high surface energy.

3. The organic transistor according to claim 1, wherein the gate insulating layer is composed of an upper layer having a surface free energy of 40 mN/m or less and a lower layer having a surface free energy of 45 mN/m or more.

4. The organic transistor according to claim 1, wherein a portion of an upper insulating layer of the gate insulating layer in contact with a part or all of the source and drain electrodes has a surface free energy of 50 mN/m or more.

5. The organic transistor according to claim 1, wherein in a portion of the gate insulating layer having a double layer structure composed of an upper layer and a lower layer, a hydrogen bonding component of a surface free energy of the upper insulating layer is 1.0 mN/m or less, and a hydrogen bonding component of a surface free energy of the lower insulating layer is 2.0 mN/m or more, and a hydrogen bonding component of a surface free energy of a portion of an insulating layer connected continuously with the upper insulating layer and adjacent to a part or all of the source and drain electrodes is 5.0 mN/m or more.

6. The organic transistor according to claim 1, wherein in a portion of the gate insulating layer having a double layer structure composed of an upper layer and a lower layer, the upper insulating layer is polyimide containing an alkyl group in a side chain thereof, and the lower insulating layer is polyimide containing no alkyl group in a side chain thereof.

7. The organic transistor according to claim 1, wherein in a portion of the gate insulating layer having a double layer structure composed of an upper layer and a lower layer, the upper insulating layer is polyimide containing an alkyl group in a side chain thereof, and the lower insulating layer is made of an inorganic insulating material.

8. The organic transistor according to claim 1, wherein in a portion of the gate insulating layer having a double layer structure composed of an upper layer and a lower layer, a layer thickness of the upper insulating layer is thinner than a layer thickness of the lower insulating layer.

9. The organic transistor according to claim 1, wherein in a portion of the lower insulating layer having a double layer structure composed of an upper layer and a lower layer, a layer thickness of the upper insulating layer is 2 nm or more and 200 nm or less and the lower insulating layer is 100 nm or more.

10. A method of manufacturing an organic transistor comprising a substrate, a gate electrode, a stacked gate insulating layer composed of two or more layers, source and drain electrodes, and an organic semiconductor layer, which method comprises the steps of:
subjecting the stacked gate insulating layer composed of two or more layers to mask exposure with ultraviolet rays having a wavelength band of 200 nm or more and 300 nm or less,
discharging an electrode material for forming source and drain electrodes onto a portion of the stacked gate insulating layer subjected to the mask exposure by using an ink-jet method, and
separating the electrode material by difference in surface free energy between the portion subjected to the mask exposure and the other portion not subjected to the mask exposure to form a channel.

11. The method of manufacturing an organic transistor according to claim 10, wherein prior to the step of subjecting the stacked gate insulating layer composed of two or more layers to mask exposure with ultraviolet rays having a wavelength band of 200 nm or more and 300 nm or less, the stacked gate insulating layer composed of two or more layers is subject to a rubbing treatment.

12. The method of manufacturing an organic transistor according to claim 10, wherein prior to or after the step of subjecting the staked gate insulating layer composed of two or more layers to the mask exposure with ultraviolet rays having a wavelength band of 200 nm or more and 300 nm or less, the staked gate insulating layer composed of two or more layers is subjected to irradiation of polarized ultraviolet rays.

13. An organic transistor having a bottom gate structure with a plurality of insulating layers, comprising a substrate, a gate electrode, a substrate insulating layer located between the substrate and the gate electrode, a gate insulating layer, source and drain electrodes, and an organic semiconductor layer, wherein the gate insulating layer has a low surface energy in a portion in proximity to the source and drain electrodes and a high surface energy in a portion in proximity to the gate electrode, and has different compositions in a layer thickness direction, and a surface free energy of the substrate insulating layer is lower than a surface free energy of a portion of the gate insulating layer in proximity to the gate electrode.

14. The organic transistor, according to claim 13, in the bottom gate structure, comprising a substrate, a gate electrode, a substrate insulating layer located between the substrate and the gate electrode, a gate insulating layer, source and drain electrodes, and an organic semiconductor layer, wherein the gate insulating layer consists of an upper layer having a low surface energy and a lower layer having a high surface energy, and a surface free energy of the substrate insulating layer is lower than the high surface free energy of the lower layer of the gate insulating layer.

15. The organic transistor according to claim 13, wherein an upper layer of the gate insulating layer has a surface free energy of 40 mN/m or less, an lower layer of the gate insulating layer has a surface free energy of 45 mN/m or more, and the substrate insulating layer has a surface free energy of 45 mN/m or more.

16. The organic transistor according to claim 13, wherein an upper layer of the gate insulating layer is an insulating layer having a surface free energy of 50 mN/m or more adjacent to a part or all of the source and drain electrodes, and the substrate insulating layer is an insulating layer having a surface free energy of 50 mN/m or more adjacent to a part or all of the gate electrode.

17. The organic transistor according to claim 13, wherein in the gate insulating layer, a hydrogen bonding component of a surface free energy of an upper layer of the insulating layer is 1.0 mN/m or less and a hydrogen bonding component of a surface free energy of an lower layer of the insulating layer is 2.0 mN/m or more, and a hydrogen bonding component of a surface free energy of a portion of an insulating layer connected continuously with the insulating layer of the upper layer and adjacent to a part or all of the source and drain electrodes is 5.0 mN/m or more; and wherein in the substrate insulating layer, a hydrogen bonding component of a surface free energy is 1.0 mN/m or less, and a hydrogen bonding component of a surface free energy of a portion of an insulating layer connected continuously with the substrate insulating layer and adjacent to a part or all of the gate electrode is 5.0 mN/m or more.

18. The organic transistor according to claim 13, wherein in the substrate insulating layer and the gate insulating layer, the substrate insulating layer and an upper layer of the gate insulating layer are polyimide containing an alkyl group in a side chain thereof, and a lower layer of the gate insulating layer is polyimide containing no alkyl group in a side chain thereof.

19. The organic transistor according to claim 13, wherein in the substrate insulating layer and the gate insulating layer, the substrate insulating layer and an upper layer of the gate insulating layer are polyimide containing an alkyl group in a side chain thereof, and a lower layer of the gate insulating layer is made of an inorganic insulating material.

20. The organic transistor according to claim 13, wherein in the substrate insulating layer and the gate insulating layer, a layer thickness of the substrate insulating layer and a layer thickness of an upper layer of the gate insulating layer are thinner than a layer thickness of a lower layer of the gate insulating layer.

21. The organic transistor according to claim 13, wherein in the substrate insulating layer and the gate insulating layer, a layer thickness of the substrate insulating layer and a layer thickness of an upper layer of the gate insulating layer are 2 nm or more and 200 nm or less, and a layer thickness of a lower layer of the gate insulating layer is 100 nm or more.

22. A method of manufacturing an organic transistor including a plurality of insulating layers and comprising a substrate, a gate electrode, a substrate insulating layer located between the substrate and the gate electrode, a staked gate insulating layer composed of two or more layers, source and drain electrodes, and an organic semiconductor layer, which method comprises the steps of:
subjecting the substrate insulating layer and the gate insulating layer to mask exposure with ultraviolet rays having a wavelength band of 200 nm or more and 300 nm or less;
discharging an electrode material for forming a gate electrode onto a part or all of a portion of the substrate insulating layer subjected to the mask exposure by an ink-jet method such that the electrode material expands to the portion subjected the mask exposure to form a gate electrode; and
discharging an electrode material for forming source and drain electrodes onto a portion of the gate insulating layer subjected to the mask exposure by an ink-jet method, and separating the electrode material by a difference in surface free energy between the portion subjected to the mask exposure and the other portion not subjected to the mask exposure to form a channel.

23. The method of manufacturing an organic transistor according to claim 22, wherein prior to the step of subjecting the stacked gate insulating layer composed of two or more layers to the mask exposure with ultraviolet rays having wavelength band of 200 nm or more and 300 nm or less, the stacked gate insulating layers composed of two or more layers is subjected to a rubbing treatment.

24. The method of manufacturing an organic transistor according to claim 22, wherein prior to or after the step of subjecting the stacked gate insulating layers composed of two or more layers to the mask exposure with ultraviolet rays having a wavelength band of 200 nm or more and 300 nm or less, the stacked gate insulating layer composed of two or more layers is subjected to irradiation of polarized ultraviolet rays.
